(19) United States
(12) Patent Application Publication
(10) Pub. No.: US 2006/0011916 A1
(43) Pub. Date: Jan. 19, 2006

(54) Substrate for epitaxial growth, process for producing the same, and multi-layered film structure

(75) Inventors: Akira Sakai, Nagoya (JP); Noriyuki Taoka, Nagoya (JP); Osamu Nakatsuka, Nagoya (JP); Shigeaki Zaima, Nagoya (JP); Yukio Yasuda, Nagoya (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: NATIONAL UNIVERSITY CORPORATION NAGOYA UNIVERSITY, Nagoya (JP)

(21) Appl. No.: 11/088,766

(22) Filed: Mar. 25, 2005

(30) Foreign Application Priority Data
Jul. 14, 2004 (JP) 2004-207782

(51) Int. Cl. H01L 29/12; H01L 21/20

(52) U.S. Cl. 257/65; 257/616; 438/502; 438/509

(57) ABSTRACT

A substrate for epitaxial growth includes a silicon-containing substrate, a silicon-germanium film, and a network-shaped structure. The silicon-germanium film is formed lamellarly on the silicon-containing substrate. The network-shaped structure is disposed adjacent to an interface between the silicon-containing substrate and the silicon-germanium film, and is composed of a 90-degree-dislocation dislocation line elongating continuously. The 90-degree-dislocation dislocation line making the network-shaped structure elongates remarkably long without being broken to short lengths interruptedly so that the 90-degree dislocation is disposed cyclically in planes parallel to the interface. Accordingly, the 90-degree dislocation is present uniformly in planes parallel to the interface. Consequently, strains in the crystal lattice of the silicon-germanium film have been uniformly relaxed more securely.

### BACKGROUND OF THE INVENTION

1. Field of the Invention

The present invention relates to a substrate for epitaxial growth, a process for producing the same, and a multi-layered film structure comprising the substrate. It is possible to use the present substrate and the present multi-layered film structure suitably for the manufacture of semiconductor devices, for example, especially for the manufacture of field-effect transistors in which strains are introduced into the channel areas.

2. Description of the Related Art

Recently, in order to speed up MOS (i.e., metal-oxide film-semiconductor) field-effect transistors, it has been studied actively to improve the carrier mobility in the channel areas by introducing tensile strains into the crystalline lattice of silicon films making the channel areas.

In order to make strained silicon films by giving tensile strains to silicon films, it is necessary to grow silicon films epitaxially on substrate layers, whose lattice constants are larger than that of silicon, by chemical deposition or physical vapor deposition. As for the substrate layers, silicon-germanium films have been used usually. Note that silicon-germanium films are formed on silicon substrates by means of epitaxial growth by chemical deposition or physical vapor deposition, have larger lattice constants than that of silicon, and are subjected to strain relaxation.

When a silicon-germanium film is grown epitaxially on a silicon (001) substrate, the silicon-germanium film grows while involving strains in itself because of lattice misfit. As the film thickness of the silicon-germanium film increases, the strains become larger. When the film thickness of the silicon-germanium film exceeds the critical film thickness, dislocations are introduced into the interface between the silicon substrate and the silicon-germanium film. The introduction of dislocations achieves the strain relaxation in the silicon-germanium film. The dislocations introduced in this instance are the 60-degree dislocation which is inherent in the diamond structure resulting from the (111) glide plane, that is, a dislocation in which a displacement vector (i.e., Burgers vector) of a dislocation makes an angle of 60 degrees with a dislocation line.

The 60-degree dislocation Burgers vector comprises an edge dislocation component in the perpendicular and horizontal direction with respect to the substrate's plane, and a screw dislocation component. Accordingly, the crystal lattice of silicon-germanium film, which is subjected to the strain relaxation by the 60-degree dislocation, inclines minutely with respect to the substrate's plane, and rotates minutely in planes parallel to the substrate's plane. Consequently, the crystal lattice makes an inhomogeneous mosaic structure in the direction of the substrate's plane.

In such a mosaic-structured silicon-germanium film, the internal strains are not relaxed isotropically and uniformly. Accordingly, even if trying to manufacture a heterojunctioned field-effect transistor structure by forming a silicon channel layer on the silicon-germanium film, it is not possible to give tensile strains to the silicon channel layer isotropically and uniformly. Consequently, the energy-band-structure modulation varies locally in the silicon channel layer. Therefore, it is not possible to achieve the aiming high carrier mobility.

Hence, the following technique has been known, for example, as disclosed in Japanese Unexamined Patent Publication (KOKAI) No. 2004-172,276. In the technique disclosed in the document, an interfacial layer capable of functioning as a dislocation control layer is formed between a silicon substrate and a silicon-germanium film, thereby introducing a 90-degree dislocation into the silicon-substrate side of the silicon-germanium film.

The technique for introducing a 90-degree dislocation utilizes a fact that, when a germanium layer (or GaAs layer) is formed on a silicon substrate, not a 60-degree dislocation, but a 90-degree dislocation is introduced into the interface between the germanium layer and the silicon substrate preferentially. That is, the technique lets the germanium (or GaAs) interfacial-layer formed on the silicon substrate function as a dislocation control layer, thereby forming a 90-degree dislocation on the silicon-substrate side of the silicon-germanium layer formed on the germanium (or GaAs) interfacial layer.

Specifically, the temperature of a silicon substrate is controlled at 200° C. Then, a 5-nm germanium interfacial layer is first formed on the silicon substrate by using a film forming method such as a molecular beam epitaxy (hereinafter abbreviated to as “MBE”) method. Subsequently, while keeping the silicon substrate at the same temperature, 200° C., a 5-nm silicon-germanium intermediate layer is formed on the germanium interfacial layer by using a film forming method such as an MBE method similarly. Note that the silicon-germanium intermediate layer is for inhibiting the lowered flatness resulting from subsequent heat treatments. Finally, the temperature of the silicon substrate is raised to 400° C., and a silicon-germanium film is formed on the silicon-germanium intermediate layer by using a film forming method such as an MBE method similarly. Thus, a germanium interfacial layer is first formed on the silicon substrate, and the resulting interfacial layer is made-to function as a dislocation control layer, thereby forming a 90-degree dislocation on the silicon-substrate side of the silicon-germanium film formed on the resultant interfacial layer.

The 90-degree dislocation thus introduced into the silicon-germanium film comprises an edge dislocation component alone in the perpendicular direction with respect to the substrate's plane. Moreover, the Burgers vector of 90-degree dislocation crosses a dislocation line orthogonally. Accordingly, the Burgers vector is free from rotary components in planes parallel to the silicon substrate's plane. Consequently, the crystal lattice of the silicon-germanium film with the 90-degree dislocation introduced is isotropic without forming a mosaic structure.

However, the conventional silicon-germanium film into which the 90-degree dislocation is introduced has the following disadvantages. The internal strains of the conventional silicon-germanium film has not been securely relaxed uniformly because the 90-degree dislocation is not disposed cyclically in planes parallel to the silicon substrate's surface.

Specifically, the conventional silicon-germanium film is formed as a structure in which the 90-degree-dislocation dislocation line is broken to short lengths interruptedly and the 90-degree dislocations with short dislocation lines are dispersed abundantly in planes parallel to the silicon substrate's plane. Thus, the conventional silicon-germanium film has not been formed as a structure in which the 90-degree dislocations are disposed cyclically. Accordingly, in the conventional silicon-germanium film, the following two parts are mixed: parts whose crystal lattice's strains have not been relaxed because no 90-degree dislocation exits; and parts whose crystal lattice's strains have been relaxed because the 90-degreed is location exits. Consequently, the crystal lattice's strains have not been securely relaxed uniformly. Note that the thickness of germanium interfacial layer and the processing temperature affect the elongation of dislocation lines introduced into the interface between silicon substrate and germanium film. Therefore, it is believed that, in the conventional silicon-germanium film, the 90-degree-dislocation dislocation lines have been broken to short lengths interruptedly and the 90-degree dislocations have not been disposed cyclically because the film thickness of the germanium interfacial layer is as thin as 5 nm and the processing temperature was as low as 400° C.

When the strains of silicon-germanium film are not relaxed uniformly, it is difficult as well to give tensile strains uniformly to the crystal lattice of silicon film which is grown epitaxially on silicon-germanium film as substrate layer. Therefore, when utilizing such a silicon film as a strained silicon channel layer, it is difficult to achieve a high carrier mobility.

### SUMMARY OF THE INVENTION

The present invention has been developed in view of the aforementioned circumstances. It is therefore an object of the present invention to accomplish uniform strain relaxation more reliably in a silicon-germanium film disposed on a silicon substrate, for instance.

A substrate for epitaxial growth according to the present invention comprises:

a silicon-containing substrate;

a silicon-germanium film formed lamellarly on the silicon-containing substrate; and

a network-shaped structure-disposed adjacent to an interface between the silicon-containing substrate and the silicon-germanium film, and composed of a 90-degree-dislocation dislocation line elongating continuously.

The term, “silicon-containing substrate,” herein means to include not only single-layered substrates comprising a simple silicon substrate but also multi-layered substrates. Note that a simple silicon substrate can contain impure elements if required or inevitably. Moreover, a multi-layered substrate comprises a simple silicon substrate, an insulation layer composed of a thermally oxidized film, such as an SiO₂ film, and formed on the silicon substrate, and a silicon layer formed on the insulation layer. Specifically, as for the silicon-containing substrate, it is possible to use single-layered silicon substrates, and multi-layered SOI (i.e., silicon on insulator) substrates comprising silicon substrates, silicon oxide film layers and silicon layers.

Moreover, the term, “90-degree dislocation” means a dislocation in which a displacement vector (i.e., Burgers vector) of a dislocation makes an angle of 90 degrees with a dislocation line.

In addition, the term, “network-shaped structure,” means structures composed of 90-degree-dislocation dislocation lines whose lengths are 0.3 μm (or 300 nm) or more, which elongate crisscross or vertically and horizontally, which cross at an angle of about 90 degrees, and which are disposed in a meshed shape. In the network-shaped structure, the intervals between the neighboring dislocation lines are not necessarily required to be equal to each other.

According to a preferable mode of the present substrate, the 90-degree-dislocation dislocation line can have a length of 0.3 μm or more.

According to another preferable mode of the present substrate, the silicon-germanium film can have a film thickness falling in a range of from 10 to 500 nm.

According to still another preferable mode of the present substrate, the silicon-germanium film can exhibit a root-mean-square surface roughness of 5 nm or less.

According to a further preferable mode of the present substrate, the silicon-germanium film can be free from a mosaic structure therein.

The term, “mosaic structure,” herein specifies such states that individual micro crystals incline in different directions with respect to the interface between the silicon-containing substrate and the silicon-germanium film so that strains are relaxed inhomogeneously within planes parallel to the interface. More specifically, as set forth in later described comparative examples, when silicon-germanium films contain the mosaic structure, the peaks of such silicon-germanium films are formed as oval shapes in a substantially horizontal direction in reciprocal lattice space two-dimensional mapping by means of an X-ray diffraction method. On the contrary, as set forth in later described examples of the present invention, when silicon-germanium films are free from the mosaic structure, the peaks of such silicon-germanium films are formed as circular shapes with good symmetry, that is, substantially perfect circular shapes, in reciprocal lattice space two-dimensional mapping by means of an X-ray diffraction method.

A first process according to the present invention is for producing a substrate for epitaxial growth, the substrate comprising a silicon-containing substrate and a silicon-germanium film formed lamellarly on the silicon-containing substrate, and comprises the steps of:

forming a germanium film lamellarly on a silicon-containing substrate;

heat-treating the silicon-containing substrate with the germanium film formed thereon in a low-temperature range of from 600 to 800° C., thereby forming a network-shaped structure disposed adjacent to an interface between the silicon-containing substrate and the germanium film and composed of a 90-degree-dislocation dislocation line elongating continuously; and

heat-treating the silicon-containing substrate with the germanium film formed-thereon in a high-temperature range of from 800 to 1,300° C., thereby forming the silicon-germanium film by diffusing silicon atoms and germanium atoms mutually between the silicon-containing substrate and the germanium film, and by mixing both silicon atoms and germanium atoms with each other.

A second process according to the present invention is for producing a substrate for epitaxial growth, the substrate comprising a silicon-containing substrate and a silicon-germanium film formed lamellarly on the silicon-containing substrate, and comprises the steps of:

forming a germanium film lamellarly on a silicon-containing substrate; and

heat-treating the silicon-containing substrate with the germanium film formed thereon in a high-temperature range of from 800 to 1,300° C., thereby forming the silicon-germanium film by diffusing silicon atoms and germanium atoms mutually between the silicon-containing substrate and the germanium film, and by mixing both silicon atoms and germanium atoms with each other, wherein a network-shaped structure is formed, the network-shaped structure disposed adjacent to an interface between the silicon-containing substrate and the germanium film and composed of a 90-degree-dislocation dislocation line elongating continuously.

According to a preferable mode of the first or second present production process, the first or second present production process can further comprise a step of further forming a silicon film lamellarly on the germanium film formed on the silicon-containing substrate; and

diffusing silicon atoms and germanium atoms mutually between the resultant silicon film and the germanium film as well in the high-temperature-range heat-treating step.

According to another preferable mode of the first or second present production process, a film thickness of the germanium film can be controlled to fall in a range of from 10 to 500 nm in the germanium-film forming step.

A multi-layered film structure according to the present invention comprises:

the substrate set forth in claim 1; and

at least one member formed on the substrate, and selected from the group consisting of silicon films, germanium films and silicon-germanium films.

### BRIEF DESCRIPTION OF THE DRAWINGS

A more complete appreciation of the present invention and many of its advantages will be readily obtained as the same becomes better understood by reference to the following detailed description when considered in connection with the accompanying drawings and detailed specification, all of which forms a part of the disclosure.

FIG. 1 is a constructional diagram for schematically illustrating a substrate for epitaxial growth and a multi-layered film structure according to Example No. 1 of the present invention.

FIGS. 2(a) through 2(d) are constructional diagrams for schematically illustrating a process according to Example No. 1 of the present invention for producing a substrate for epitaxial growth.

FIGS. 3(a) through 3(c) are constructional diagrams for schematically illustrating a process according to Example No. 3 of the present invention for producing a substrate for epitaxial growth.

FIGS. 4(a) and 4(b) are images of planes of substrates for epitaxial growth according to Example No. 3 of the present invention, images which were taken by a transmission electron microscope, wherein FIG. 4(a) shows the image on the substrate produced in Example No. 3-2 and FIG. 4(b) shows the image on the substrate produced in Example No. 3-3.

FIGS. 5(a) and 5(b) are images of cross sections of substrates according to Example No. 3 of the present invention for epitaxial growth, images which were taken by a transmission electron microscope, wherein FIG. 5(a) shows the image on the substrate produced in Example No. 3-2 and FIG. 5(b) shows the image on the substrate produced in Example No. 3-3.

FIGS. 6(a) and 6(b) show the results of reciprocal lattice space two-dimensional mappings on sample substrates according to Example No. 3 of the present invention and Comparative Example No. 1 for epitaxial growth, reciprocal lattice space two-dimensional mappings which were measured by an X-ray diffraction method, wherein FIG. 6(a) shows the result on the sample substrate produced in Example No. 3-2 and FIG. 6(b) shows the result on the sample substrate produced in Comparative Example No. 1.

FIG. 7 shows the results of surface roughness measurements, using an atomic force microscope, for silicon-germanium films of substrates for epitaxial growth produced in Example No. 1, Example No. 2 and Example No. 3, and illustrates how the surface roughness depended on heat-treatment temperatures.

FIGS. 8(a) and 8(b) are images of a sample substrate for epitaxial growth, which underwent a low-temperature-range heat-treatment step according to Example No. 1-1 in Example No. 1 of the present invention, images which were taken by a transmission electron microscope, wherein FIG. 8(a) shows the image on a plane of the sample substrate and FIG. 8(b) shows the image on a cross section of the sample substrate.

FIG. 9 is an image on a plane of a sample substrate for epitaxial growth, which underwent a low-temperature-range heat-treatment step in the same manner as Example No. 1-1 in Example No. 1 of the present invention except that a film thickness of its germanium film was changed to 20 nm, image which was taken by a transmission electron microscope.

FIG. 10 is an image on a plane of a substrate, produced in Comparative Example No. 2, for epitaxial growth, image which was taken by a transmission electron microscope.

### DETAILED DESCRIPTION OF THE PREFERRED EMBODIMENTS

Having generally described the present invention, a further understanding can be obtained by reference to the specific preferred embodiments which are provided herein for the purpose of illustration only and not intended to limit the scope of the appended claims.

The present substrate for epitaxial growth comprises a silicon-containing substrate, and a silicon-germanium film formed on the silicon-containing substrate. Moreover, a network-shaped structure is disposed adjacent to an interface between the silicon-containing substrate and the silicon-germanium film. In addition, the network-shaped structure is composed of a 90-degree-dislocation dislocation line which elongates continuously. Note that the 90-degree-dislocation dislocation line making the network-shaped structure elongates remarkably long without being broken to short lengths interruptedly so that -the 90-degree dislocation is disposed cyclically in planes parallel to the interface. Accordingly, the 90-degree dislocation is present uniformly in planes parallel to the interface. Consequently, strains in the crystal lattice of the silicon-germanium film have been uniformly relaxed more securely. Thus, the formation of such a network-shaped structure composed of the 90-degree-dislocation dislocation line makes the silicon-germanium film free from mosaic structures.

Therefore, when a silicon film, a germanium film or another silicon-germanium film is grown epitaxially on the silicon-germanium film of the present substrate for epitaxial growth to make a multi-layered film structure, it is possible to uniformly give tensile strains to the resulting silicon film, germanium film or silicon-germanium film. Hence, when the resultant multi-layered film structure is applied to field-effect transistors, for example, to utilize the resulting silicon film, germanium film or silicon-germanium film as a strained silicon channel layer, strained germanium channel layer or strained silicon-germanium channel layer, it is possible to achieve a high carrier mobility in the resultant strained channel layer.

Note herein that the present multi-layered film structure comprises the present substrate for epitaxial growth; and at least one member formed on the present substrate, and selected from the group consisting of silicon films, germanium films and silicon-germanium films. Accordingly, the present multi-layered film structure can be applied to field-effect transistors, for example, to utilize the silicon films, germanium films or silicon-germanium films as strained silicon channel layers, strained germanium channel layers or strained silicon-germanium channel layers. Consequently, it is possible to achieve a high carrier mobility in the resultant strained channel layers.

In the present substrate for epitaxial growth and multi-layered film structure, the 90-degree-dislocation dislocation line can preferably have a length of 0.3 μm (or 300 nm) or more. When the 90-degree-dislocation dislocation line has a length shorter than 0.3 μm, it is difficult to form the network-shaped structure. The longer the 90-degree-dislocation dislocation line is the more preferable it is. The 90-degree-dislocation dislocation line can further preferably have a length of 10 μm or more, and can especially preferably have a length of 100 μm. When making integrated circuits utilizing the present substrate for epitaxial growth or multi-layered film structure, the 90-degree-dislocation dislocation line can preferably elongate continuously over the entire integrated circuits substantially, further preferably from an opposite end of the integrated circuits to the other opposite end thereof substantially. Note that, in view of the chip sizes of ordinary integrated circuits falling in a range of from 10 to 30 mm approximately, the upper limit of the length of the 90-degree-dislocation dislocation line can be 50 mm approximately. Moreover, the 90-degree-dislocation dislocation line can preferably elongate continuously over the entire silicon-containing substrate substantially, further preferably from an opposite end of the silicon-containing substrate to the other opposite end thereof substantially, and the network-shaped structure can preferably be formed over the entire silicon-containing substrate substantially. When the 90-degree-dislocation dislocation line elongates continuously over the entire silicon-containing substrate substantially so that the network-shaped structure is formed over the entire silicon-containing substrate substantially, it is possible to make the strain relaxation of the silicon-germanium film isotropic and uniform more securely over the silicon-germanium film entirely.

Thus, the network-shaped structure can preferably be composed of the 90-degree-dislocation dislocation line which elongates to have a length of 0.3 μm or more, further preferably 10 μm or more, especially preferably 100 μm or more. In other words, the network-shaped structure can preferably comprise a structure in which the 90-degree dislocation is disposed cyclically beyond a length of 0.3 μm or more, further preferably 10 μm or more, especially preferably 100 μm or more.

Moreover, the silicon-germanium film can preferably have a film thickness falling in a range of from 10 to 500 nm, especially preferably from 20 to 100 nm. When the film thickness of the silicon-germanium film is too thick, the film forming requires such large energy and long time that it is disadvantageous in view of cost. On the other hand, when the film thickness of the silicon-germanium film is too thin, the 90-degree-dislocation dislocation line has been broken to short lengths interruptedly so that it is difficult to form the network-shaped structure composed of the continuously long 90-degree-dislocation dislocation line. Note that, when the present substrate for epitaxial growth is utilized to field-effect transistors, for example, the silicon-germanium film, which is thinned out on nano order, can contribute to thinning out such field-effect transistors.

Moreover, the silicon-germanium film can preferably exhibit a root-mean-square surface roughness of 5 nm or less, especially preferably 1 nm or less. The surface roughness of the silicon-germanium film affects the crystallinity of silicon films, for example, which are grown epitaxially on the silicon-germanium film. Accordingly, when the root-mean-square surface roughness of the silicon-germanium film is reduced, it is possible to inhibit the surface roughness of the silicon-germanium film from lowering the carrier mobility in the resulting silicon films. Note that, as described later, it is possible to control the surface roughness of the silicon-germanium film by changing the film forming method of a germanium film or a silicon film which is carried out before subjecting a silicon-containing substrate with a germanium film formed to a heat treatment in a high-temperature range of from 800 to 1,300° C. Note that the lower limit of the silicon-germanium film's root-mean-square surface roughness can preferably be 0.3 nm or more, especially preferably be 0.1 nm or more.

In addition, in the silicon-germanium film, a compositional ratio of silicon to germanium (i.e., Si:Ge) can preferably be Si:Ge=8:2 to 2:8 by atomic percent, especially preferably be 7:3 to 6:4 by atomic percent. The compositional ratio of silicon to germanium in silicon-germanium films relates to the number of dislocation lines required for, the strain relaxation of silicon-germanium films and the intervals between dislocation lines. For instance, as the germanium content lowers, the number of dislocation lines required for the strain relaxation of silicon-germanium films decreases so that the intervals between dislocation lines widen.

Note that, as described later, it is possible to properly control the compositional ratio of silicon to germanium in the silicon-germanium film by forming or not forming a silicon film on the germanium film formed on the silicon-containing substrate, by changing the thickness of a formed silicon film formed thereon, or by changing the heating temperature or heating time in subjecting the silicon-containing substrate with the germanium film formed to a heat treatment in a high-temperature range of from 800 to 1,300° C.

Moreover, a plurality of the 90-degree-dislocation dislocation lines, making the network-shaped structure, can preferably be disposed at intervals falling in a range of from 10 to 45 nm, especially preferably from 25 to 35 nm. When the intervals between the 90-degree-dislocation lines making the network-shaped structure are too narrow, the difference between the lattice constant of the silicon-containing substrate and that of the silicon-germanium film enlarges too much, as a result, unexpected threading dislocations have increased. On the other hand, the intervals between the 90-degree-dislocation dislocation lines, which have been widened too much, are not preferable in view of the object of the present invention, because such overly widened intervals represent states that the strains of silicon-germanium films have not been relaxed sufficiently, or states that silicon-germanium films comprise germanium in lesser amounts.

The present substrate for epitaxial growth can be produced by the first or second present process for producing a substrate for epitaxial growth.

The first present process for producing a substrate for epitaxial growth comprises the steps of: forming a germanium film on a silicon containing substrate; heat-treating the silicon-containing substrate with the germanium film formed in a low-temperature range of from 600 to 800° C.; and heat-treating the silicon-containing substrate with the germanium film formed in a high-temperature range of from 800 to 1,300° C.

In the germanium-film forming step, a germanium film is formed lamellarly on a silicon-containing substrate. In this instance, it is preferable to control the thickness of the germanium film in a range of from 10 to 500 nm as described above. The method of forming the germanium film is not limited in particular. It is possible to form the germanium film on the silicon-containing substrate by using known film-forming methods, such as an MBE method, while heating the silicon-containing substrate at a predetermined temperature of from 200 to 400° C.

In the low-temperature-range heat-treating step, the silicon-containing substrate with the germanium film formed is heat-treated in a low-temperature range of from 600 to 800° C., thereby forming a network-shaped structure disposed adjacent to an interface between the silicon-containing substrate and the germanium film and composed of a 90-degree-dislocation dislocation line elongating continuously.

When the heating temperature is less than 600° C. in the low-temperature-range heat-treating step, the 90-degree-dislocation dislocation line is likely to be broken to short lengths interruptedly so that it is -difficult or impossible to form the network-shaped structure composed of the 90-degree-dislocation dislocation line elongating continuously. Note that the heating temperature can preferably be 700° C. or more in the low-temperature-range heat-treating step. On the other hand, when the heating temperature is more than 800° C. in the low-temperature-range heat-treating step, silicon atoms and germanium atoms diffuse mutually between the silicon-containing substrate and the germanium film. If such is the case, it is difficult to distinguish between the first present production process and the second production process. Moreover, the heating time can preferably be controlled in a range of from 1 to 10 minutes approximately in the low-temperature-range heat-treating step. In addition, the heating temperature can further preferably fall in a range of from 700 to 800° C., especially preferably from 730 to 770° C., in the low-temperature-range heat-treating step.

In the high-temperature-range heat-treating step, the silicon-containing substrate with the germanium film formed is heat-treated in a high-temperature range of from 800 to 1,300° C., thereby forming a strain-relaxed silicon-germanium film by diffusing silicon atoms and germanium atoms mutually between the silicon-containing substrate and the germanium film and mixing both silicon atoms and germanium atoms with each other.

When the heating temperature is less than 800° C. in the high-temperature-range heat-treating step, it is difficult to have silicon atoms and germanium atoms diffused mutually between the silicon-containing substrate and the germanium film sufficiently so that both atoms hardly mix with each other satisfactorily. Accordingly, it is difficult or impossible to form the silicon-germanium film. On the other hand, when the heating-temperature is more than 1,300° C. in the high-temperature-range heat-treating step, the network-shaped structure falls apart because the heating temperature is close to the melting point of the silicon-germanium film. Consequently, the heating temperature can preferably fall in a range of from 1,000 to 1,200° C., especially preferably from 1,100 to 1,200° C., in the high-temperature-range heat-treating step. Moreover, the heating time can preferably be controlled in a range of from 1 to 300 minutes approximately in the high-temperature-range heat-treating step.

In addition, it is possible to arbitrarily control the compositional ratio of silicon to germanium in the silicon-germanium film and the cyclic intervals between the 90-degree-dislocation dislocation lines making the network-shaped structure by controlling the heat-treating conditions in the high-temperature-range heat-treating step. For example, increasing the heat-treating temperature facilitates the solid phase diffusion of silicon atoms from the silicon-containing substrate to the germanium film. Accordingly, it is possible to lower the compositional ratio of germanium to silicon in the silicon-germanium film. Moreover, as the compositional ratio of germanium to silicon lowers in the silicon-germanium film, the number of the 90-degree-dislocation dislocation lines required for the strain relaxation of the silicon-germanium film decreases. Consequently, it is possible to widen the cyclic intervals between the 90-degree-dislocation dislocation lines making the network-shaped structure.

Note that the network-shaped structure composed of the 90-degree-dislocation dislocation line, which is formed in the low-temperature-range heat-treating step, is preserved as it is after it is subjected to the high-temperature-range heat treatment in the-high-temperature-range heat-treating step.

On the other hand, the second present process for producing a substrate for epitaxial growth comprises the steps of: forming a germanium film on a silicon-containing substrate; and heat-treating the silicon-containing substrate with the germanium film formed in a high-temperature range of from 800 to 1,300° C. Note that the germanium-film forming step is the same as that of the first present production process.

The second present process for producing a substrate for epitaxial growth gets rid of the low-temperature-range heat-treating step in the first present production process. Specifically, in the second present production process, by heat-treating the silicon-containing substrate with the germanium film formed in the high-temperature-range heat-treating step alone, not only a network-shaped structure, disposed adjacent to an interface between the silicon-containing substrate and the germanium film and composed of a 90-degree-dislocation dislocation line elongating continuously, is formed, but also silicon atoms and germanium atoms are diffused mutually between the silicon-containing substrate and the germanium film and both silicon atoms and germanium atoms mix with each other, and thereby a strain-relaxed silicon-germanium film is formed.

Therefore, the second present production process can shorten the production of the present substrate for epitaxial growth and can reduce the production cost thereof, because it abbreviates a heat-treating step, the low-temperature-range heat-treating step, compared with the first present production process.

Similarly to the high-temperature-range heat-treating step in the first present production process, the heating temperature of the high-temperature-range heat-treating step in the second present production process can preferably fall in a range of from 1,000 to 1,200° C., especially preferably from 1,100 to 1,200° C. Likewise, the heating time can preferably be controlled in a range of from 1 to 300 minutes approximately in the high-temperature-range heat-treating step.

Moreover, similarly to the high-temperature-range heat-treating step in the first present production process, it is possible to arbitrarily control the compositional ratio of silicon to germanium in the silicon-germanium film and the cyclic intervals between the 90-degree-dislocation dislocation lines making the network-shaped structure by controlling the heat-treating conditions in the high-temperature-range heat-treating step in the second present production process.

Note that the first or second present process for producing a substrate for epitaxial growth can preferably further comprise a step of further forming a silicon film lamellarly on the germanium film formed on the silicon-containing substrate; and diffusing silicon atoms and germanium atoms mutually between the resultant silicon film and the germanium film as well in the high-temperature-range heat-treating step. When a silicon film is further formed lamellarly on the germanium film formed on the silicon-containing substrate, and when silicon atoms and germanium atoms are diffused mutually as well between the resultant silicon film and the germanium film in the high-temperature-range heat-treating step, the solid-phase diffusion of silicon atoms to the germanium film is facilitated. As a result, it is possible to greatly lower the compositional ratio of germanium to silicon in the silicon-germanium film, or to quickly lower the compositional ratio of germanium to silicon. Moreover, the further added silicon-film forming step is advantageous in view of enhancing the superficial flatness of the silicon-germanium film.

In the further added silicon-film forming step, a silicon film is further formed lamellarly on the germanium film formed on the silicon-containing film. In this instance, the silicon film can preferably be formed in a film thickness of from 1 to 50 nm, especially preferably from 5 to 20 nm. When the film thickness of the silicon film is too thick, it is disadvantageous in view of cost because it takes much energy and time for forming the silicon film. On the other hand, when the film thickness of the silicon film is too thin, the advantageous effect of enhancing the superficial flatness of the silicon-germanium film diminishes.

Moreover, the method of forming the silicon film is not limited in particular. It is possible to form the silicon film on the germanium film formed on the silicon-containing substrate by using known film-forming methods, such as an MBE method, while heating the silicon-containing substrate at a predetermined temperature of 600° C. or less. Note that it is possible to make the silicon film by growing amorphous silicon layers at room temperature.

In addition, in the first present process for producing a substrate for epitaxial growth, it is preferable to carry out the further added silicon-film forming step after forming the network-shaped structure composed of the 90-degree-dislocation dislocation line adjacent to an interface between the silicon-containing substrate and the germanium film. In this way, it is possible to upgrade the structural homogeneity of the silicon-germanium film.

### EXAMPLES

The present invention will be hereinafter described in detail with reference to specific examples. However, the present invention is not limited to the following specific examples.

### Example No. 1

### Example No. 1-1

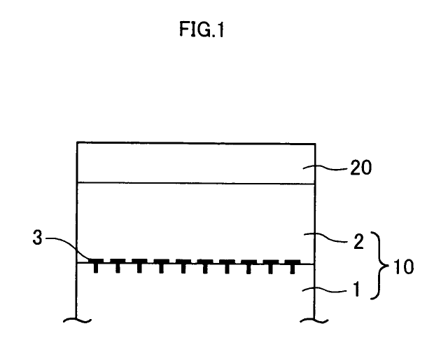

FIG. 1 schematically illustrates a constructional diagram of a multi-layered film structure according to Example No. 1-1 of the present invention. As shown in the drawing, the multi-layered film structure comprised a substrate 10 for epitaxial growth, and a silicon film 20 formed on the substrate 10. The substrate 10 comprised a silicon substrate 1 (i.e., the claimed silicon-containing substrate), and a silicon-germanium film 2 which was formed on the silicon substrate 10 and whose film thickness was 70 nm. Moreover, network-shaped structures 3 composed of the 90-degree-dislocation dislocation lines were disposed adjacent to the interface between the silicon substrate 1 and the silicon-germanium film 2. Note that the compositional ratio of silicon to germanium was Si:Ge=7:3 by atomic percent in the silicon-germanium film 2.

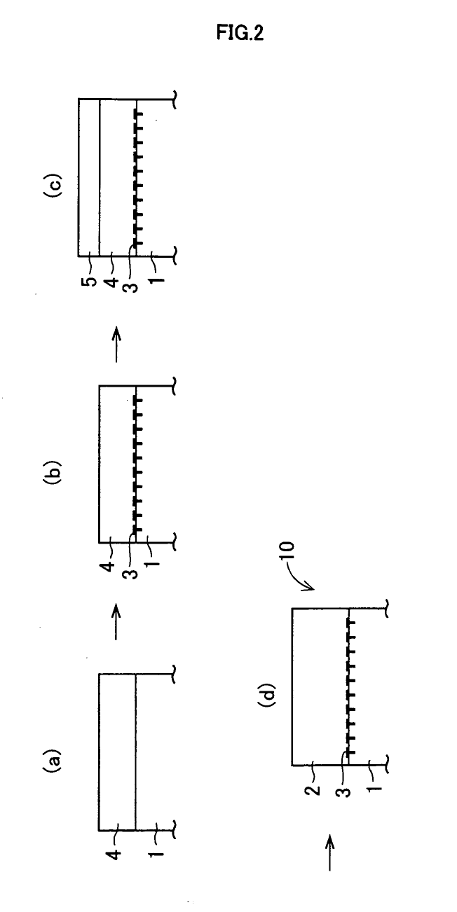

The multi-layered film structure according to Example No. 1-1 of the present invention was produced in the following manner using a production process illustrated schematically in FIG. 2.

### Germanium-Film Forming Step

A silicon (001) substrate 1 was prepared, and was heated to 200° C. While keeping the temperature of the silicon substrate 1 at 200° C., a germanium film 4 was grown epitaxially on the silicon substrate 1 using an MBE method. Thus, as illustrated in FIG. 2(a), the germanium film 4 was formed on the silicon substrate 1 in a film thickness of 35 nm.

### Low-Temperature-Range Heat-Treating Step

Then, the silicon substrate 1 was subjected to a low-temperature-range heat treatment by heating the silicon substrate 1 to 700° C. and holding thereat for 10 minutes. Thus, as illustrated in FIG. 2(b), the network-shaped structures 3 composed of the 90-degree-dislocation dislocation lines were formed at the interface between the silicon substrate 1 and the germanium film 4. Hence, the germanium film 4 was strain-relaxed.

### Silicon-Film Forming Step

Moreover, the silicon substrate 1 was cooled to 300° C. While keeping the temperature of the substrate 1 at 300° C., a silicon film 5 was grown epitaxially on the germanium film 4 using an MBE method. Thus, as illustrated in FIG. 2(c), the silicon film 5 was formed on the germanium 4 in a film thickness of 17 nm, thereby making a precursor of the multi-layered film structure.

### High-Temperature-Range Heat-Treating Step

Finally, the resulting precursor was subjected to a high-temperature-range heat treatment by heating the precursor to 950° C. and holding thereat for 2 minutes. Thus, silicon atoms and germanium atoms were diffused mutually between the germanium film 4 and the silicon substrate 1, and between the germanium film 4 and the silicon film 5. Hence, as illustrated in FIG. 2(d), the strain-relaxed silicon-germanium film 2 was formed on the silicon substrate 1.

Note that the network-shaped structures 3, formed at the low-temperature-range heat-treating step and composed of the 90-degree-dislocation dislocation lines, were kept being formed at the interface even after the high-temperature-range heat-treating step.

In this way, the substrate 10 for epitaxial growth was completed. Moreover, the substrate 10 was cooled to 600° C. While keeping the temperature of the substrate 10 at 600° C., a silicon film 20 was grown epitaxially on the silicon-germanium film 2 using an MBE method. Thus, as illustrated in FIG. 1, the silicon film 20 was formed on the top of the substrate 10, thereby completing the multi-layered film structure.

### Example No. 1-2

Except that the heating temperature was changed to 1,000° C. at the high-temperature-range heat-treating step in Example No. 1-1, a multi-layered film structure according to Example No. 1-2 of the present invention was produced in the same manner as Example No. 1-1.

### Example No. 1-3

Except that the heating temperature was changed to 1,1000° C. at the high-temperature-range heat-treating step in Example No. 1-1, a multi-layered film structure according to Example No. 1-3 of the present invention was produced in the same manner as Example No. 1-1.

### Example No. 2

### Example No. 2-1

Except that an amorphous silicon layer was grown epitaxially at room temperature on the germanium film 4 using an MBE method and an amorphous silicon film 5 was formed on the germanium film 4 in a film thickness of 17 nm at the silicon-film forming step in Example No. 1-1, a multi-layered film structure according to Example No. 2-1 of the present invention was produced in the same manner as Example No. 1-1, and comprised the same elements as those of Example No. 1-1.

### Example No. 2-2

Except that an amorphous silicon layer was grown epitaxially at room temperature on the germanium film 4 using an MBE method and an amorphous silicon film 5 was formed on the germanium film 4 in a film thickness of 17 nm at the silicon-film forming step in Example No. 1-1, a multi-layered film structure according to Example No. 2-2 of the present invention was produced in the same manner as Example No. 1-2, and comprised the same elements as those of Example No. 1-2.

### Example No. 2-3

Except that an amorphous silicon layer was grown epitaxially at room temperature on the germanium film 4 using an MBE method and an amorphous silicon film 5 was formed on the germanium film 4 in a film thickness of 17 nm at the silicon-film forming step in Example No. 1-1, a multi-layered film structure according to Example No. 2-3 of the present invention was produced in the same manner as Example No. 1-3, and comprised the same elements as those of Example No. 1-3.

### Example No. 3

### Example No. 3-1

A multi-layered film structure according to Example No. 3-1 of the present invention comprised the same elements as those of Example No. 1-1 basically.

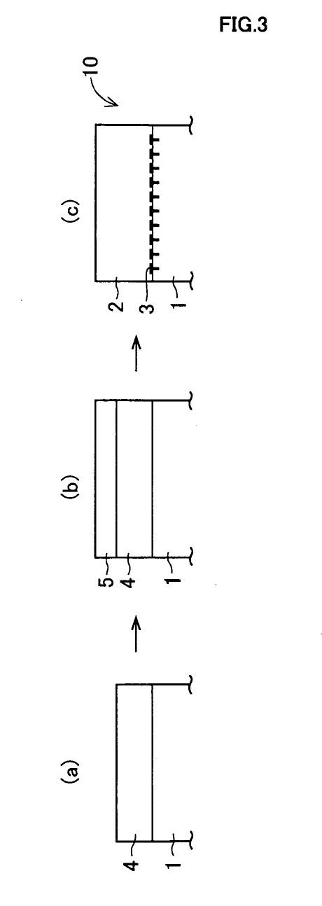

The multi-layered film structure according to Example No. 3-1 of the present invention was produced in the following manner using a production process-illustrated schematically in FIG. 3.

### Germanium-Film Forming Step

The same silicon (001) substrate 1 as that of Example No. 1-1 was prepared, and was heated to 200° C. While,.keeping the temperature of the silicon substrate 1 at 200° C., a germanium film 4 was grown epitaxially on the silicon substrate 1 using an MBE method. Thus, as illustrated in FIG. 3(a), the germanium film 4 was formed on the silicon substrate 1 in a film thickness of 35 nm.

### Silicon-Film Forming Step

Then, the silicon substrate 1 was cooled to room temperature, and an amorphous silicon layer was grown epitaxially at room temperature on the germanium film 4 using an MBE method. Thus, as illustrated in FIG. 3(b), an amorphous silicon film 5 was formed on the germanium 4 in a film thickness of 17 nm, thereby making a precursor of the multi-layered film structure.

### High-Temperature-Range Heat-Treating Step

Finally, the resulting precursor was subjected to a high-temperature-range heat treatment by heating the precursor to 950° C. and holding thereat for 2 minutes. Thus, the network-shaped structures 3 composed of the 90-degree-dislocation dislocation lines were formed at the interface between the silicon substrate 1 and the germanium film 4, and simultaneously therewith silicon atoms and germanium atoms were diffused mutually between the germanium film 4 and the silicon substrate 1, and between the germanium film 4 and the amorphous silicon film 5. Hence, as illustrated in FIG. 3(c), the strain-relaxed silicon-germanium film (or silicon-germanium mixed-crystal film) 2 was formed on the silicon substrate 1.

In this way, the substrate 10 for epitaxial growth was completed. Moreover, a silicon film 20 was formed on the top of the substrate 10 in the same manner as Example No. 1-1, thereby completing the multi-layered film structure.

### Example No. 3-2

Except that the heating temperature was changed to 1,000° C. at the high-temperature-range heat-treating step in Example No. 3-1, a multi-layered film structure according to Example No. 3-2 of the present invention was produced in the same manner as Example No. 3-1.

### Example No. 3-3

Except that the heating temperature was changed to 1,100° C. at the high-temperature-range heat-treating step in Example No. 3-1, a multi-layered film structure according to Example No. 3-3 of the present invention was produced in the same manner as Example No. 3-1.

### Comparative Example No. 1

### First Silicon-Germanium-Film Forming Step

The same silicon (001) substrate as that of Example No. 1-1 was prepared, and was heated to 400° C. While keeping the temperature of the silicon substrate at 400° C., a first silicon-germanium layer was grown epitaxially on the silicon substrate using an MBE method. Thus, a first silicon-germanium film was formed on the silicon substrate in a film thickness of 25 nm. Note that the compositional ratio of silicon to germanium was Si:Ge=7:3 by atomic percent in the first silicon-germanium film.

### Silicon-Film Forming Step

Then, while keeping the temperature of the silicon substrate at 400° C., a silicon layer was grown epitaxially on the first silicon-germanium film using an MBE method. Thus, a silicon film was formed on the first silicon-germanium film in a film thickness of 5 nm.

### Low-Temperature-Range Heat-Treating Step

Moreover, the silicon substrate was subjected to a low-temperature-range heat treatment by heating the silicon substrate to 600° C. and holding thereat for 5 minutes. Thus, the network-shaped structures composed of the 60-degree-dislocation dislocation lines were formed at the interface between the silicon substrate and the first silicon-germanium film. Hence, the first silicon-germanium film was strain-relaxed.

### Second Silicon-Germanium-Film Forming Step

Finally, while keeping the temperature of the silicon substrate at 600° C., a second silicon-germanium layer was grown epitaxially on the silicon film using an MBE method. Thus, a second silicon-germanium film was formed on the silicon film in a film thickness of 100 nm. Note that the compositional ratio of silicon to germanium was Si:Ge=7:3 by atomic percent in the second silicon-germanium film. In this way, a substrate for epitaxial growth according to Comparative Example. No. 1 was completed.

### Evaluation

### Evaluation on Plane by Transmission Electron Microscope

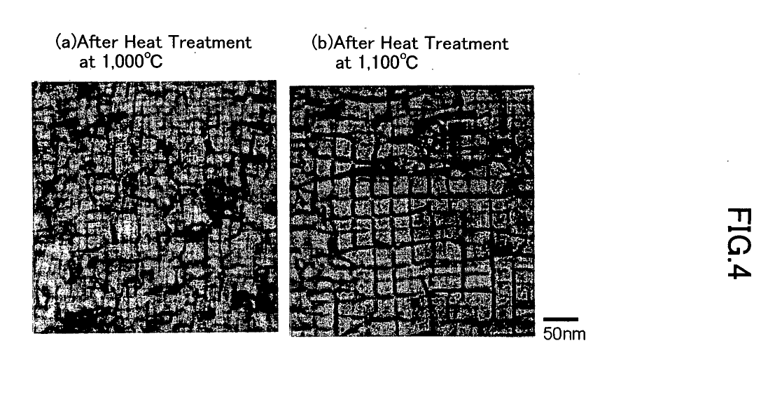

FIG. 4(a) shows an image on a plane of the substrate for epitaxial growth produced in Example No. 3-2, image which was taken by a transmission electron microscope. Note that the substrate was heat-treated at 1,000° C. in the high-temperature-range heat-treating step.

Likewise, FIG. 4(b) shows an image on a plane of the substrate for epitaxial growth produced in Example No. 3-3, image which was taken by a transmission electron microscope. Note that the substrate was heat-treated at 1,100° C. in the high-temperature-range heat-treating step.

In the drawings, note that the lines appearing crisscross represent the 90-degree-dislocation dislocations lines which were formed adjacent to the interface between the silicon substrate 1 and the silicon-germanium film 2.

From FIGS. 4(a) and 4(b), the following are apparent. The 90-degree-dislocation dislocation lines elongated continuously beyond a length of about 500 nm or more within the entire observed region without being broken to short lengths interruptedly. Moreover, the assembly of the 90-degree-dislocation dislocation lines formed the network-shaped structures 3, meshed cyclic structures. In addition, the network-shaped, structures 3 were composed of the 90-degree dislocations which were disposed cyclically beyond a length of 500 nm or more.

Moreover, it is seen that the intervals between the 90-degree-dislocation dislocation lines widened as the heat treatment temperature increased in the high-temperature-range heat-treating step. Specifically, as shown in FIG. 4(a), an average interval between the 90-degree-dislocation dislocation lines were about 15 nm when the heat treatment temperature was 1,000° C. in the high-temperature-range heat-treating step. On the other hand, as-shown in FIG. 4(b), an average interval between the 90-degree-dislocation dislocation lines were about 35 nm when the heat treatment temperature was 1,100° C. in the high-temperature-range heat-treating step. The fact implies that, as a result of silicon's facilitated solid-phase diffusion, the silicon-germanium film 2, which comprises less germanium, is formed. As the germanium content lowers in the silicon-germanium film 2, the number of the 90-degree-dislocation dislocation lines required for strain relaxation decreases. Moreover, when being heat-treated at high temperatures, individual dislocations move in the perpendicular and horizontal directions facilitatedly. As a result, dislocation dispositions are rearranged so as to relax strains arising in the silicon-germanium film 2. In this instance, dislocations overlap as well in the vertical direction with respect to the silicon substrate 1. The bold 90-degree-dislocation dislocation lines with high contrast appearing in FIG. 4(b) represent such double-overlapping 90-degree-dislocation dislocation lines.

These actions change the cyclic intervals between the 90-degree-dislocation dislocation lines, which make the network-shaped structures 3, consequently. The fact indicates that it is possible to form the strain-relaxed silicon-germanium film 2 which has arbitrary compositions by controlling the heat treatment conditions in the high-temperature-range heat-treating step.

Note that the substrates 10 for epitaxial growth produced in Example No. 1 and Example No. 2 also yielded the same results as described above.

### Evaluation on Cross Section by Transmission Electron Microscope

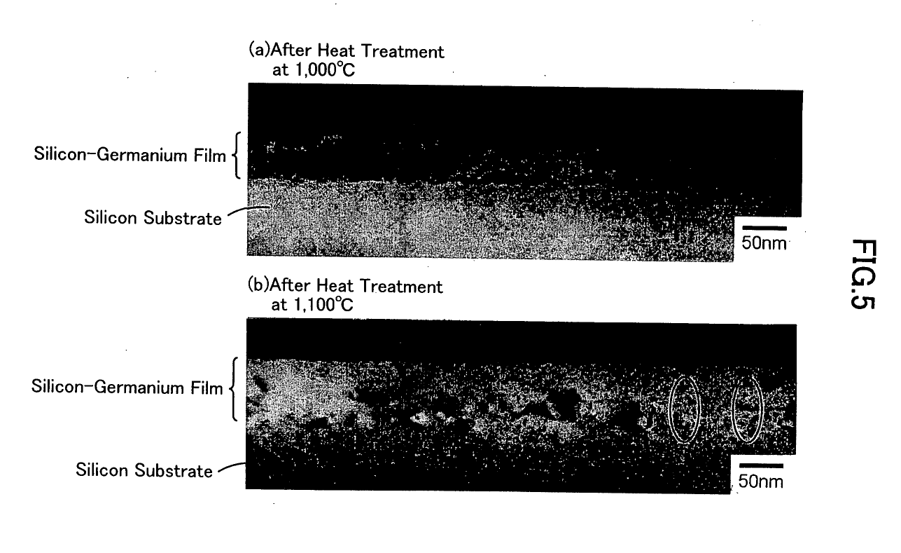

FIG. 5(a) shows an image on a cross section of the substrate for epitaxial growth produced in Example No. 3-2, image which was taken by a transmission electron microscope. Note that the substrate was heat-treated at 1,000° C. in the high-temperature-range heat-treating step.

Likewise, FIG. 5(b) shows an image on a cross section of the substrate for epitaxial growth produced in Example No. 3-3, image which was taken by a transmission electron microscope. Note that the substrate was heat-treated at 1,100° C. in the high-temperature-range heat-treating step.

From FIG. 5(a) and 5(b), it is appreciated that the single-layered silicon-germanium film 2 was formed in which silicon and germanium were mixed thoroughly. Note that black dots appear cyclically in the interface between the silicon substrate 1 and the silicon-germanium film 2. The black dots are equivalent to the cross sections of the 90-degree-dislocation dislocation lines, which were disposed cyclically. Moreover, as enclosed with the ovals of FIG. 5(b), it is seen that the 90-degree-dislocation dislocation lines are lined up in the perpendicular direction with respect to the silicon substrate 1 when the heat treatment temperature was 1,100° C. in the high-temperature-range heat-treating step. Note that the parts, in which the 90-degree-dislocation dislocation lines are lined up in the perpendicular direction with respect to the silicon substrate 1, designate the bold 90-degree-dislocation dislocation lines with high contrast shown in FIG. 4(b).

### Evaluation by X-Ray Diffraction Analysis

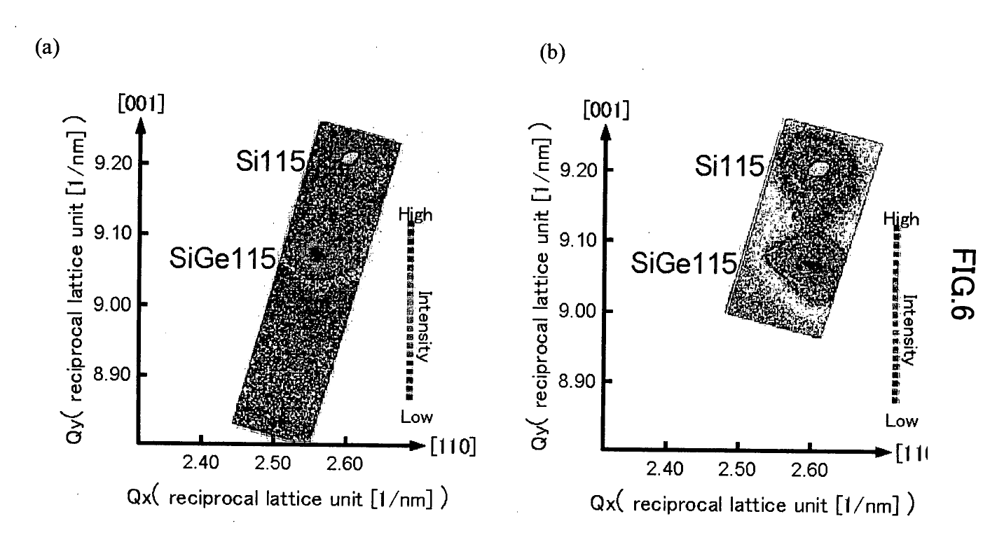

The substrate for epitaxial growth produced in Example No. 3-3, which was heat-treated at 1,100° C. in the high-temperature-range heat-treating step, was subjected to an X-ray diffraction analysis in order to examine the reciprocal lattice space two-dimensional mapping. FIG. 6(a) shows the results.

Likewise, the substrate for epitaxial growth produced in Comparative Example No. 1 was subjected to an X-ray diffraction analysis in order to examine the reciprocal lattice space two-dimensional mapping. FIG. 6(b) shows the results.

Note that, in the drawings, the vertical axis specifies the reciprocal of crystal-lattice size in the horizontal direction with respect to the surface of the silicon substrate, and the horizontal axis specifies the reciprocal thereof in the horizontal direction with respect thereto. Moreover, the peak positions of signal intensities indicate the sizes of crystal planes which were possessed by observed crystals. In addition, in both drawings, it is possible to observe peaks which represent the (115) plane of the Si crystal lattice of the silicon substrate and that of the Si—Ge crystal lattice of the silicon-germanium film.

From FIG. 6(b), it is seen that the peak of the silicon-germanium film formed in Comparative Example No. 1 was formed as an oval shape which widened in the horizontal direction. This fact implies that inhomogeneity was present in the silicon-germanium film in view of the horizontal strain relaxation, compared with the perpendicular strain relaxation. That is, it suggests that the silicon-germanium film had a mosaic structure which was composed of crystals confined individually in fine regions in the horizontal direction. Moreover, it also suggests that the individual fine crystals inclined slightly in different directions with respect to the horizontal surface of the silicon substrate and each of them was strain-relaxed differently.

On the contrary, as can be seen from FIG. 6(a), the peak of the silicon-germanium film 2 in the substrate 10 for epitaxial growth produced in Example No. 3-3 was formed as a circle shape with good symmetry (or a virtually perfect circle). Thus, it is understood that no such mosaic structure as appeared in the silicon-germanium film in Comparative Example No. 1 arose in the silicon-germanium film 2 in Example No. 3-3 so that uniform strain relaxation was accomplished in a wide range over the entire silicon substrate 1. Moreover, it is understood from the peak position that the silicon-germanium film 2 exhibited a substantially equal lattice constant in the perpendicular and horizontal directions with respect to the silicon substrate 1. This fact implies that the silicon-germanium film 2 was strain-relaxed fully. That is, when the network-shaped structure composed of the 90-degree-dislocation dislocation lines is formed, it is possible to produce the silicon-germanium film 2, which has a uniform structure within planes and which is strain-relaxed completely, in such a remarkably thin film thickness as dozens of nm.

### Surface Roughness Evaluation with Atomic Force Microscope

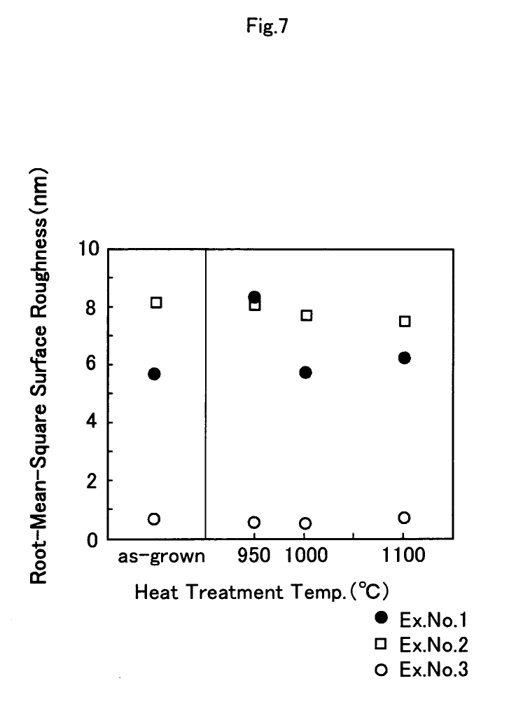

Each of the substrates 10 for epitaxial growth, produced in Example Nos. 1-1 through 1-3, Example Nos. 2-1 through 2-3 and Example Nos. 3-1 through 3-3, was measured for the surface roughness of the silicon-germanium film 2 with an atomic force microscope. FIG. 7 illustrates the heat-treatment temperature dependency of the surface roughness as a result of the measurements.

Note that, in FIG. 7, the horizontal axis specifies the heating temperature in the high-temperature-range heat-treating step, and the vertical axis specifies the root-mean-square surface roughness of the silicon-germanium film 2. Moreover, the solid circles of FIG. 7 designate Example Nos. 1-1 through 1-3, the blank squares designate Example Nos. 2-1 through 2-3, and the blank circles designate Example Nos. 3-1 through 3-3. In addition, in FIG. 7, the term, “as-grown,” indicates samples prior to the high-temperature-range heat treatments.

From FIG. 7, it is seen that, even when the silicon-germanium films 2 were strain-relaxed by the 90-degree dislocation similarly, the surface flatness of the resulting silicon-germanium films 2 depended greatly on the methods for forming the precursors of the multi-layered film structure, methods which were carried out before the high-temperature-range heat-treating step, the final heat-treating step.

Specifically, in the substrates 10 for epitaxial growth produced in Example Nos. 3-1 through 3-3, it is understood that it was possible to form the silicon-germanium films 2 with such a small surface roughness as the root-mean-square surface roughness of 1 nm or less.

### Evaluation on Si/Ge Interface after Low-Temperature-Range Heat-Treating Step

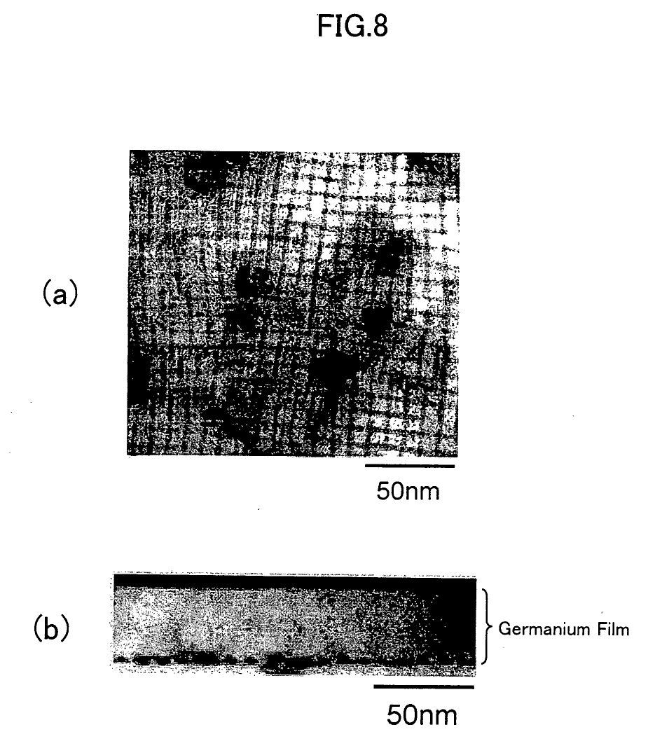

FIG. 8(a) shows an image on a plane of a sample obtained after the low-temperature-range heat-treating step in Example No. 1-1, image which was taken by a transmission electron microscope. Moreover, FIG. 8(b) shows an image on a cross section of the sample, image which was taken by a transmission electron microscope.

In FIG. 8(a), note that the lines appearing crisscross represent the 90-degree-dislocation dislocations lines which were formed adjacent to the interface between the silicon substrate 1 and the germanium film 4.

From FIG. 8(a), it is apparent that the 90-degree-dislocation dislocation lines elongated continuously over the observed region entirely without being broken to short lengths interruptedly and the assembly of the 90-degree-dislocation dislocation lines formed the network-shaped structures 3, meshed cyclic structures.

Moreover, in FIG. 8(b), it is possible to observe the cross sections of the 90-degree-dislocation dislocation lines as black dots. Accordingly, it is seen that an array of the 90-degree dislocations, which were disposed cyclically, was formed at the interface between the silicon substrate 1 and the germanium film 4.

In addition, from FIG. 8(a), it is possible to estimate that an average interval between the 90-degree-dislocation dislocation lines was about 10 nm. When predicting the strain relaxation proportion of the germanium film 4 resulting from the 90-degree dislocations from the estimated average interval between the 90-degree-dislocation dislocation lines, it is believed that the germanium film 4 was strain-relaxed fully. Note that the lattice constant of the germanium film 4, which was measured using an X-ray diffraction analysis, coincided with the germanium film 4 which was strain-relaxed completely. Therefore, it is understood that the complete strain relaxation of the germanium film 4 was achieved by the network-shaped structures, which were composed of the 90-degree-dislocation dislocation lines and which were formed at the interface between the silicon substrate 1 and the germanium film 4 after the low-temperature-range heat-treating step in Example No. 1-1.

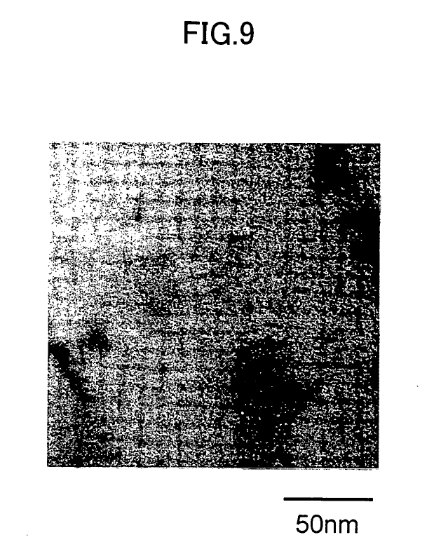

Moreover, except that the film thickness of the germanium film 4 was changed from 35 nm to 20 nm, a sample was prepared in the same manner as the above-described sample which was obtained after the low-temperature-range heat-treating step in Example No. 1-1. FIG. 9 shows an image on a plane of the sample, image which was taken by a transmission electron microscope.

In FIG. 9 as well, it is possible to observe the network-shaped structures, which were composed of the 90-degree-dislocation dislocation lines, similarly to the germanium film 4 whose film thickness was 35 nm. The average interval between the 90-degree-dislocation dislocation lines in the sample whose germanium film 4 had a film thickness of 20 nm was virtually equal to that in the sample whose germanium film 4 had a film thickness of 35 nm. Accordingly, it is understood that the germanium film 4 whose film thickness was 20 nm was strain-relaxed fully as well. Consequently, it is appreciated that the network-shaped structures, which were composed of the continuous 90-degree-dislocation dislocation lines, could form the germanium film 4, which was strain-relaxed completely.

However, note that the low-temperature-range heat-treating step alone can simply produce the germanium film 4 as a strain-relaxed layer and can only achieve films which exhibit the germanium's own lattice constant. This results from the fact that the low-temperature-range heat-treating step, which was carried out at such a low temperature as 700° C., for such a short period of time as 10 minutes, could hardly diffuse germanium atoms and silicon atoms so that germanium atoms and silicon atoms were little mixed with each other. Therefore, in order to achieve strain-relaxed layers which exhibit arbitrary lattice constants, it is required to form the silicon-germanium film 2 which is produced by way of the high-temperature-range heat-treating step and whose lattice constant is changeable by modifying the mixing or compositional ratio, and it is needed to strain-relax the silicon-germanium film 2 by the network-shaped structures which are composed of the continuous 90-degree-dislocation dislocation lines.

### Comparative Example No. 2

### Germanium Interfacial Film Forming Step

The same silicon (001) substrate as that of Example No. 1-1 was prepared, and was heated to 200° C. While keeping the temperature of the substrate at 200° C., a germanium interfacial layer was grown epitaxially on the silicon substrate using an MBE method. Thus, a germanium interfacial film was formed on the silicon substrate in a film thickness of 2.5 nm.

### Silicon-Germanium Intermediate Film Forming Step

Then, while keeping the temperature of the substrate at the same temperature, 200° C., a silicon-germanium intermediate film was formed on the germanium interfacial film in a film thickness of 5 nm by an MBE method. Note that the compositional ratio of silicon to germanium was Si:Ge=7:3 by atomic percent in the silicon-germanium intermediate film.

### Silicon-Germanium Film Forming Step

Moreover, the silicon substrate was heated to 400° C. While keeping the temperature of the substrate at 400° C., a silicon-germanium film was formed on the silicon-germanium intermediate film in a film thickness of 65 nm by an MBE method. Note that the compositional ratio of silicon to germanium was Si:Ge=7:3 by atomic percent in the silicon-germanium film.

### Silicon Film Forming Step

In addition, while keeping the temperature of the substrate at the same temperature, 400° C., a silicon film was formed on the silicon-germanium film in a film thickness of 5 nm by an MBE method, thereby making a precursor of a multi-layered film structure.

### Heat-Treating Step

Finally, the precursor was subjected to a heat treatment at 700° C. for 10 minutes, thereby completing a substrate for epitaxial growth.

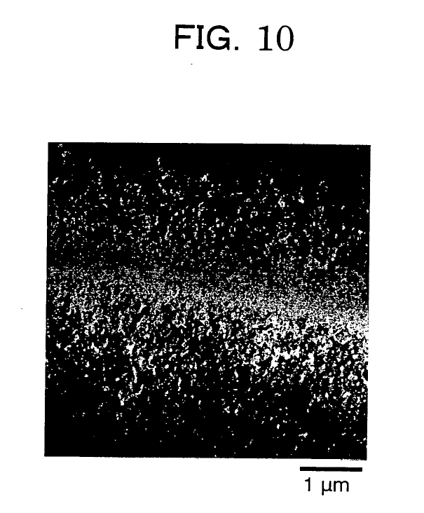

FIG. 10 shows an image on a plane of the resultant substrate for epitaxial growth, image which was taken by a transmission electron microscope. From the drawing, it is seen that structures, which were composed of dislocations with such remarkably short lengths of 100 nm or less, appear to be dispersed irregularly-within planes parallel to the silicon substrate. By observing the cross section of the substrate with a transmission electron microscope, it was possible to confirm that many of the dislocations were the 90-degree dislocations. However, the structures were apparently free from the 90-degree dislocations which were disposed cyclically. This fact is believed to result from the fact that the entire germanium interfacial film was strained less because the germanium interfacial film had such a thin film thickness as 5 nm. That is, no large strains, which were driving forces for elongating the 90-degree dislocations, had been given sufficiently to the germanium interfacial film. Accordingly, it is believed that the elongation of the 90-degree-dislocation dislocation lines had terminated when the 90-degree-dislocation dislocation lines elongated to very short lengths, though the individual 90-degree dislocations occurred. Moreover, the maximum heat treatment temperature was such a low temperature as 700° C. Consequently, it is believed that the low heat-treatment temperature, which did not give the germanium interfacial film necessary heat energy for moving the 90-degree dislocations, is one of the causes that the 90-degree-dislocation dislocation lines had not elongated sufficiently.

Therefore, in order to form the network-shaped structures which are composed of the cyclically-disposed 90-degree dislocations, it is possible to say that the following are regarded important: giving the germanium interfacial film large lattice strains to a certain extent by thickening the germanium interfacial film adequately; and facilitating the elongation of generated 90-degree dislocations by subjecting the germanium interfacial film to higher-temperature heat treatment.

Having now fully described the present invention, it will be apparent to one of ordinary skill in the art that many changes and modifications can be made thereto without departing from the spirit or scope of the-present invention as set forth herein including the appended claims.

What is claimed is:

1. A substrate for epitaxial growth, the substrate comprising:
a silicon-containing substrate;
a silicon-germanium film formed lamellarly on the silicon-containing substrate; and
a network-shaped structure disposed adjacent to an interface between the silicon-containing substrate and the silicon-germanium film, and composed of a 90-degree-dislocation dislocation line elongating continuously.

2. The substrate set forth in claim 1, wherein the 90-degree-dislocation dislocation line has a length of 0.3 μm or more.

3. The substrate set forth in claim 1, wherein the silicon-germanium film has a film thickness falling in a range of from 10 to 500 nm.

4. The substrate set forth in claim 1, wherein the silicon-germanium film exhibits a root-mean-square surface roughness of 5 nm or less.

5. The substrate set forth in claim 1, wherein the silicon-germanium film is free from a mosaic structure therein.

6. A process for producing a substrate for epitaxial growth, the substrate comprising a silicon-containing substrate and a silicon-germanium film formed lamellarly on the silicon-containing substrate, the process comprising the steps of:
forming a germanium film lamellarly on a silicon-containing substrate;
heat-treating the silicon-containing substrate with the germanium film formed thereon in a low-temperature range of from 600 to 800° C., thereby forming a network-shaped structure disposed adjacent to an interface between the silicon-containing substrate and the germanium film and composed of a 90-degree-dislocation dislocation line elongating continuously; and
heat-treating the silicon-containing substrate with the germanium film formed thereon in a high-temperature range of from 800 to 1,300° C., thereby forming the silicon-germanium film by diffusing silicon atoms and germanium atoms mutually between the silicon-containing substrate and the germanium film, and by mixing both silicon atoms and germanium atoms with each other.

7. The process set forth in claim 6 further comprising a step of further forming a silicon film lamellarly on the germanium film formed on the silicon-containing substrate; and
diffusing silicon atoms and germanium atoms mutually between the resultant silicon film and the germanium film as well in the high-temperature-range heat-treating step.

8. The process set forth in claim 6, wherein a film thickness of the germanium film is controlled to fall in a range of from 10 to 500 nm in the germanium-film forming step.

9. A process for producing a substrate for epitaxial growth, the substrate comprising a silicon-containing substrate and a silicon-germanium film formed lamellarly on the silicon-containing substrate, the process comprising the steps of:
forming a germanium-film lamellarly on a silicon-containing substrate; and
heat-treating the silicon-containing substrate with the germanium film formed thereon in a high-temperature range of from 800 to 1,300° C., thereby forming the silicon-germanium film by diffusing silicon atoms and germanium atoms mutually between the silicon-containing substrate and the germanium film, and by mixing both silicon atoms and germanium atoms with each other, wherein a network-shaped structure is formed, the network-shaped structure disposed adjacent to an interface between the silicon-containing substrate and the germanium film and composed of a 90-degree-dislocation dislocation line elongating continuously.

10. The process set forth in claim 9 further comprising a step of further forming a silicon film lamellarly on the germanium film formed on the silicon-containing substrate; and
diffusing silicon atoms and germanium atoms mutually between the resultant silicon film and the germanium film as well in the high-temperature-range heat-treating step.

11. The process set forth in claim 9, wherein a film thickness of the germanium film is controlled to fall in a range of from 10 to 500 nm in the germanium-film forming step.

12. A multi-layered film structure, comprising:
the substrate set forth in claim 1; and
at least one member formed on the substrate, and selected from the group consisting of silicon films, germanium films and silicon-germanium films.
